(19) United States
(12) Patent Application Publication
(10) Pub. No.: US 2013/0050956 A1
(43) Pub. Date: Feb. 28, 2013

(54) Photovoltaic Junction Module

(71) Applicants: Yong Wang, Shanghai (CN); Xiaoqun Chen, Shanghai (CN)

(72) Inventors: Yong Wang, Shanghai (CN); Xiaoqun Chen, Shanghai (CN)

(21) Appl. No.: 13/593,967

(22) Filed: Aug. 24, 2012

(30) Foreign Application Priority Data
Aug. 31, 2011 (CN) 201120325209.7

(51) Int. Cl. H05K 7/00

(52) U.S. Cl. 361/728

(57) ABSTRACT

A photovoltaic junction module is provided, which includes a housing, an overmolded assembly, and a cable. The overmolded assembly includes an electrical assembly and a plastic body for enclosing the electrical assembly therein. The overmolded assembly is detachably mounted to the housing. The cable extends into the housing and detachably and electrically connects to the electrical assembly.

### CROSS-REFERENCE TO RELATED APPLICATION

This application claims priority under 35 U.S.C. §119 to Chinese Patent Application No. 201120325209.7 filed on Aug. 31, 2011.

### FIELD OF THE INVENTION

The invention relates to a photovoltaic junction module, and more particularly, to a photovoltaic junction module having a photovoltaic junction box.

### BACKGROUND

Generally, electrical elements used in a known photovoltaic junction module (as shown in FIGS. 1 and 2) must be sealed to prevent the electrical elements from exposure to water, moisture and dust, for example.

As shown in FIG. 1, electrical elements may include, for example, a plurality of diodes 3, a plurality of conductive terminals 4, 5, and etc. are pre-assembled on a circuit board 2, and then cables 6, 7 are soldered to a positive conductive terminal 4 and a negative conductive terminal 5, respectively. In such way, as shown in FIG. 1, a pre-assembled known electrical assembly 1 is produced.

After the pre-assembled known electrical assembly 1 of FIG. 1 is prepared, the pre-assembled known electrical assembly 1 is placed into an injection mold to perform an overmolding process on it, thereby forming a plastic housing 8 overmolded on the pre-assembled known electrical assembly 1 and wholly enclosing the pre-assembled known electrical assembly 1 therein, as shown in FIG. 2. Accordingly, all of the electrical elements 2, 3, 4, 5 of the pre-assembled known electrical assembly 1 are sealed in the plastic housing 8 to protect the electrical elements from exposure to water, moisture and dust, for example.

One advantage of the known photovoltaic junction module shown in FIGS. 1 and 2 is that the pre-assembled known electrical assembly 1 directly contacts the plastic housing 8, instead of the ambient air. Since the plastic housing 8 has a larger heat radiation area than the known electrical assembly 1 and has a higher heat radiation coefficient than the ambient air, the heat generated by the known electrical assembly 1 can be more effectively radiated away from the known electrical assembly 1.

However, in the known photovoltaic junction module shown in FIGS. 1 and 2, if one electrical element of the known electrical assembly 1 fails, then the whole known photovoltaic junction module must be discarded, because the known electrical assembly 1 is completely enclosed in the plastic housing 8 and it cannot be individually replaced. As a result, this increases the cost of the known electrical assembly 1. Furthermore, a gap may occur between the cable 6 or 7 and the plastic housing 8 at a joint 81 or 82 of the cable 6 or 7 to the plastic housing 8 due to the thermal expansion or the thermal contraction. Accordingly, water, moisture and dust can enter into the plastic housing 8 through the gap, and it may cause a short circuit among the electrical elements or even burn out some electrical elements.

### SUMMARY

A photovoltaic junction module, according to the invention, is provided to overcome at least one aspect of the above mentioned disadvantages, among others.

The photovoltaic junction module includes a housing, an overmolded assembly, and a cable. The overmolded assembly includes an electrical assembly and a plastic body for enclosing the electrical assembly therein. The overmolded assembly is detachably mounted to the housing. The cable extends into the housing and detachably and electrically connects to the electrical assembly.

### BRIEF DESCRIPTION OF THE DRAWINGS

The above and other features of the present invention will become more apparent by describing in detail embodiments thereof with reference to the accompanying drawings, in which:

FIG. 1 is an top perspective view of a known electrical assembly of a known photovoltaic junction module;

FIG. 2 is a top perspective view of the known photovoltaic junction module formed by overmolding a plastic housing on the known electrical assembly of FIG. 1;

FIG. 3 is a perspective view of a overmolded assembly of a photovoltaic junction module according to the invention;

FIG. 4 is a perspective view of a housing of the photovoltaic junction module according to the invention;

FIG. 5 is a perspective view of the overmolded assembly of FIG. 3 assembled with the housing of FIG. 4;

FIG. 6 is a perspective view of a seal device positioned between a cable and the housing of FIG. 4; and

FIG. 7 is a perspective view of a sealing ring of the seal device shown in FIG. 6.

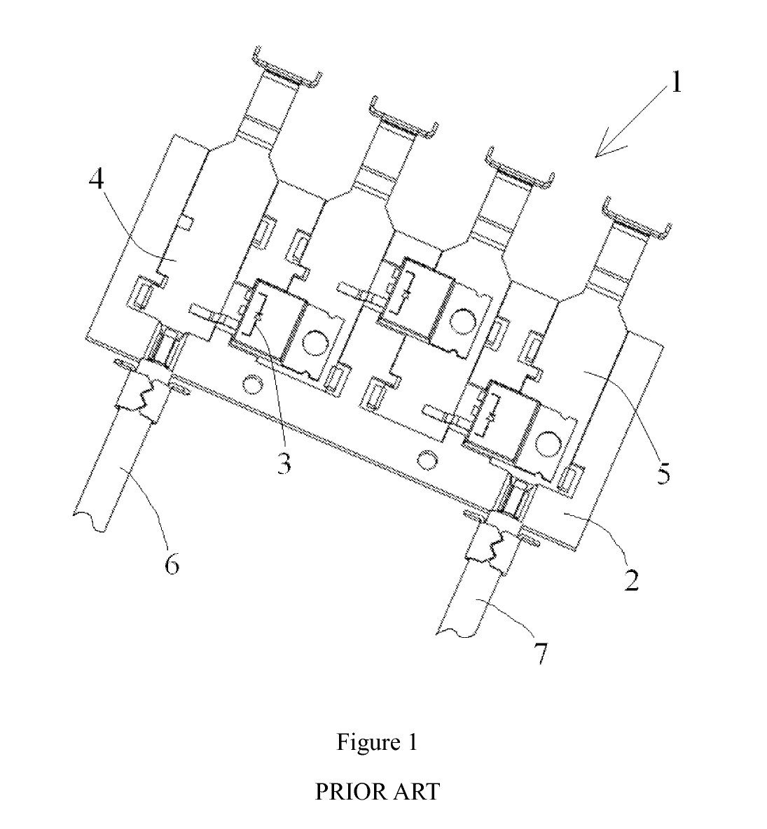

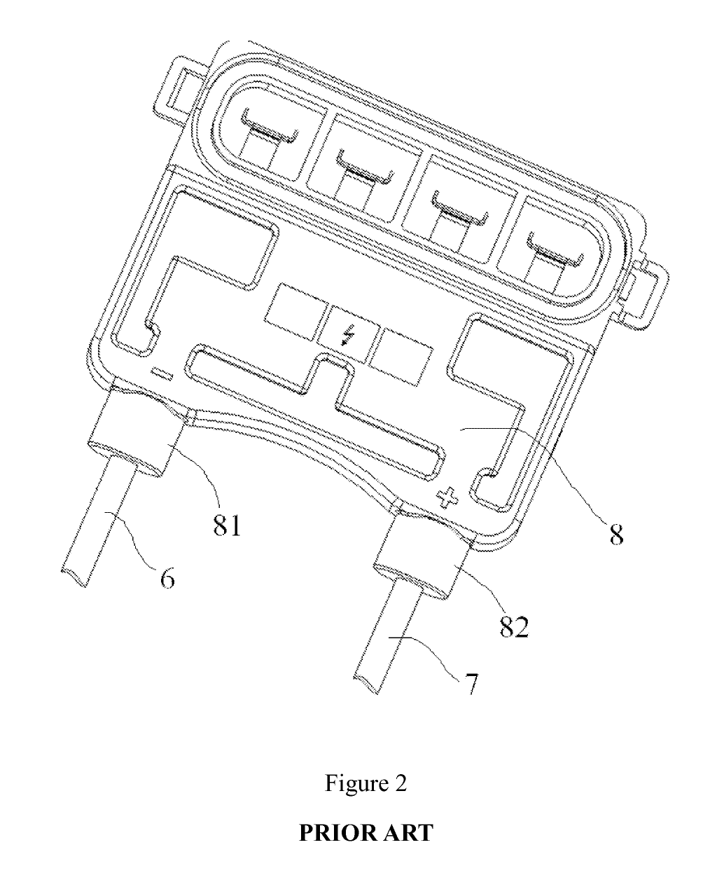

### DETAILED DESCRIPTION OF THE EMBODIMENT(S)

The embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

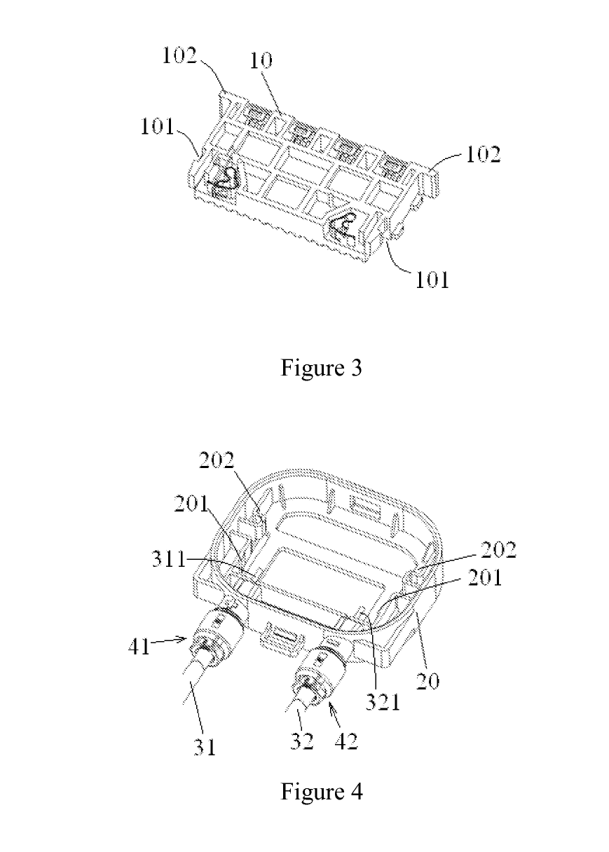

Now with reference to FIG. 3 an overmolded assembly 10 for a photovoltaic junction module according to the invention is shown, and includes an electrical assembly and a plastic body for enclosing the electrical assembly therein.

In the shown embodiment, the electrical assembly may include at least one diode and at least one conductive terminal. However, it should be noted that the electrical assembly of the invention does not include cables 31, 32 (shown in FIG. 4) and connectors (not shown) connected to the cables 31, 32.

In an embodiment of the invention, the plastic body is formed by overmolding the plastic on the electrical assembly prior to assembly with the housing 20.

As shown in FIGS. 3-5, the overmolded assembly 10 is detachably mounted to the housing 20.

In an embodiment shown in FIG. 4, a pair of guides 201 is formed on an inner wall of the housing 20, and as shown in FIG. 3, a pair of guide receiving passageways 101 is formed on an outer wall of the overmolded assembly 10. In this way, the overmolded assembly 10 may be detachably mounted in the housing 20 by mating the guides 201 with the guide receiving passageways 101.

Furthermore, in another embodiment of the invention, as shown in FIG. 4, a pair of guide receiving passageways 202 is formed on the inner wall of the housing 20, and as shown in FIG. 3, a pair of guides 102 is formed on the outer wall of the overmolded assembly 10. Accordingly, the overmolded assembly 10 may be detachably mounted in the housing 20 by mating the guides 201, 102 with the guide receiving passageways 101, 202, respectively.

However, the invention is not limited to this, the overmolded assembly 10 may be detachably mounted in the housing 20 by other manners, for example, by screwing or snapping, or other technologies known to the art.

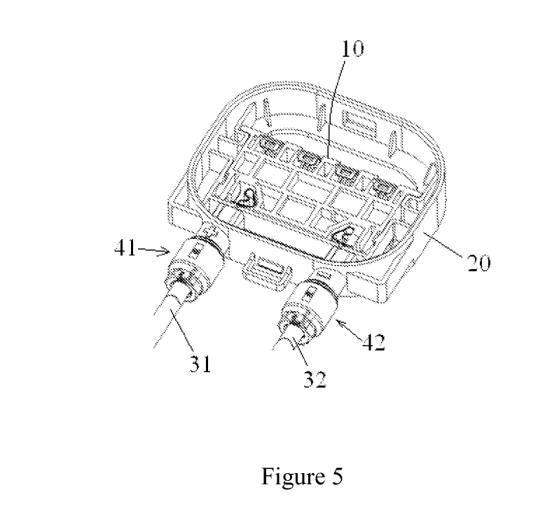

As shown in FIGS. 4-5, the photovoltaic junction module according to the invention includes a positive cable 31 and a negative cable 32. The cables 31, 32 extend into the housing 20 and are detachably and electrically connected to a positive conductive terminal (not shown) and a negative conductive terminal (not shown) of the electrical assembly in the overmolded assembly 10, respectively. For example, in an exemplary embodiment, the positive and negative cables 31, 32 elastically contact with the positive and negative conductive terminals, respectively, to electrically connect the cables 31, 32 and the electrical assembly.

In order to effectively prevent water, moisture and dust from entering into the housing 20 from joints of the cables 31, 32 to housing 20, in an exemplary embodiment of the invention, a first seal device 41 is provided between the housing 20 and the positive cable 31, a second seal device 42 is provided between the housing 20 and the negative cable 32.

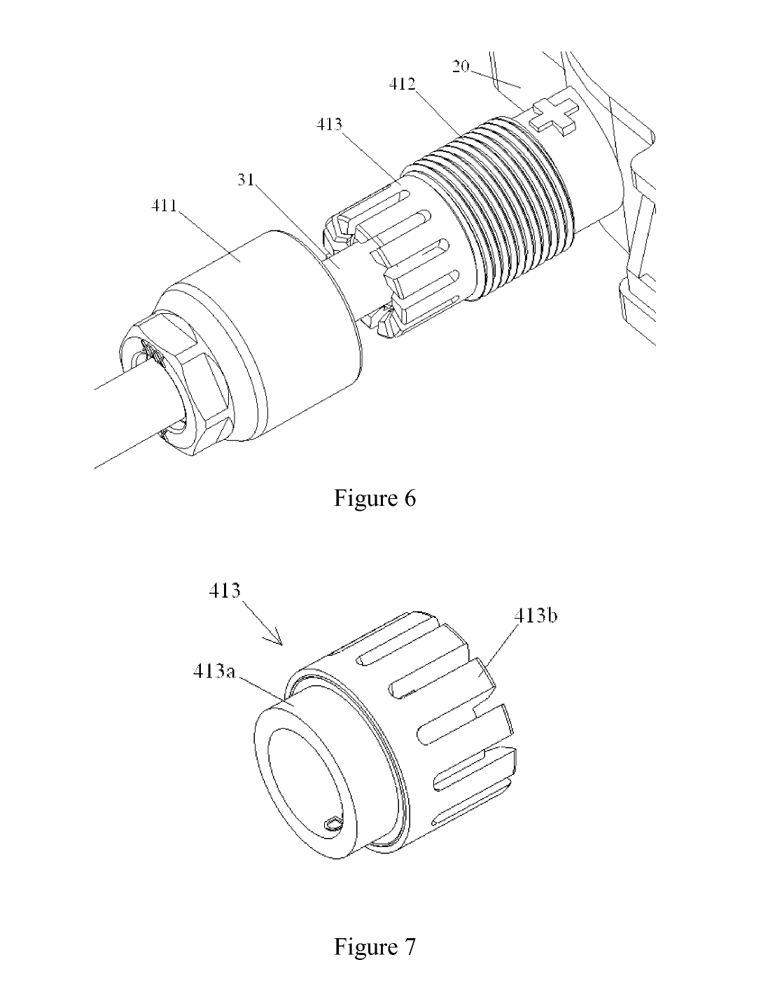

In the embodiment shown in FIGS. 6-7, the first and second seal devices 41, 42 are identical, and hereafter only the first seal device 41 is described in detail, for sake of brevity.

As shown in FIGS. 6-7, the first seal device 41 includes a threaded sleeve 412, a nut 411 and a sealing ring 413. The threaded sleeve 412 extends outwardly from an outer wall of the housing 20 and may be integrally molded with the housing 20. The nut 411 is in correspondence to the threaded sleeve 412. The sealing ring 413 is located between the threaded sleeve 412 and the nut 411 and is positioned in the nut 411.

As shown in FIG. 6, the cable 31 sequentially passes through the nut 411, the sealing ring 413, and the threaded sleeve 412, and enters into the housing 20.

As shown in FIGS. 4-6, when the nut 411 is screwed onto the threaded sleeve 412 to compress the sealing ring 413 therebetween, the sealing ring 413 is tightly wrapped around the cable 31. In this way, the joints of the cables 31, 32 to the housing 20 are sealed to prevent the water, moisture and dust from entering into the housing 20, and the cables 31, 32 are reliably fixed on the housing 20 to prevent the cables 31, 32 from being pulled out of and disconnected from the conductive terminals of the electrical assembly.

As shown in FIGS. 6-7, the sealing ring 413 includes a sleeve-like base 413a and a compression portion 413b integrally connected with the sleeve-like base 413a. In the embodiment shown in FIGS. 6-7, the sleeve-like base 413a is inserted into the threaded sleeve 412. The compression portion 413b includes a plurality of teeth spacedly arranged around a ring end of the sleeve-like base 413a. The nut 411 is configured to compress the compression portion 413b of the sealing ring 413.

In an embodiment of the present invention, the housing 20, the nut 411, and the threaded post 412 may be all made of the plastic.

In various embodiments of the invention, the electrical assembly is pre-overmoded in a plastic body to form a overmolded assembly, and the overmolded assembly is detachably mounted in a housing, therefore, when the electrical assembly fails, the operator may replace only the overmolded assembly with a new electrical assembly, instead of replacing the entire photovoltaic junction module. It saves the cost and simplifies the replacement operation. Also, heat generated by the electrical assembly is effectively radiated away from the photovoltaic junction module. In addition, the photovoltaic junction module more effectively prevents water, moisture and dust from entering into the electrical assembly.

Although several embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

What is claimed is:

1. A photovoltaic junction module, comprising:
a housing;
an overmolded assembly detachably mounted to the housing and having an electrical assembly and a plastic body for enclosing the electrical assembly therein; and
a cable extending into the housing and being detachably and electrically connected to the electrical assembly.

2. The photovoltaic junction module according to claim 1, further comprising a seal between the housing and the cable.

3. The photovoltaic junction module according to claim 2, wherein the seal is integrally molded with the housing and includes a threaded sleeve extending outwardly from an outer wall of the housing.

4. The photovoltaic junction module according to claim 3, wherein the seal further includes a nut being threadable onto the threaded sleeve.

5. The photovoltaic junction module according to claim 4, wherein the seal further includes a sealing ring positioned between the threaded sleeve and the nut such that the cable sequentially passes through the nut, the sealing ring and the threaded sleeve.

6. The photovoltaic junction module according to claim 5, wherein the nut is threaded onto the threaded sleeve compressing the sealing ring therebetween.

7. The photovoltaic junction module according to claim 5, wherein the sealing ring includes a base inserted into the threaded sleeve.

8. The photovoltaic junction module according to claim 7, wherein the sealing ring further includes a compression portion having a plurality of teeth arranged around a ring end of the base.

9. The photovoltaic junction module according to claim 8, wherein the nut is configured to compress the compression portion of the sealing ring.

10. The photovoltaic junction module according to claim 1, further comprising a guide provided on the overmolded assembly or the housing.

11. The photovoltaic junction module according to claim 10, further comprising a guide receiving passageway on the other of the overmolded assembly or the housing.

12. The photovoltaic junction module according to claim 11, wherein the overmolded assembly is detachably mounted in the housing by mating the guide with the guide receiving passageway.

13. The photovoltaic junction module according to claim 1, wherein the electrical assembly includes a diode and a conductive terminal.

14. The photovoltaic junction module according to claim 13, wherein the cable elastically contacts the conductive terminal to electrically connect the cable and the electrical assembly.
